(19) United States
(12) Patent Application Publication
(10) Pub. No.: US 2025/0266252 A1
(43) Pub. Date: Aug. 21, 2025

(54) COLLIMATOR FOR PRODUCTION OF PIEZOELECTRIC LAYERS WITH TILTED C-AXIS ORIENTATION

(71) Applicant: BIOMENSIO LTD, Tampere (FI)

(72) Inventors: Matthias SCHREITER, Munich (DE); Christoph KIENER, Munich (DE); Yves KÜSTERS, Munich (DE); Georg BODAMMER, Munich (DE); Stephan BUCHHOLZ, Munich (DE); Jyrki KAITILA, Kauniainen (FI); Rudolf FREYTAG, Munich (DE)

(21) Appl. No.: 18/857,785

(22) PCT Filed: Apr. 20, 2023
(86) PCT No.: PCT/FI2023/050220

§ 371 Date: Oct. 17, 2024

(30) Foreign Application Priority Data
Apr. 21, 2022 (FI) 20225334

(51) Int. Cl. H01J 37/34; C23C 14/34

(52) U.S. Cl. CPC H01J 37/3447; C23C 14/34

(57) ABSTRACT

According to an aspect, there is provided a collimator for tilted c-axis thin-film deposition comprising a collimator body. The collimator body comprises an array of holes for limiting directions of deposition of particles. The collimator body is a singular monolithic element.

### TECHNICAL FIELD

The embodiments relate to apparatuses for manufacture of piezoelectric layers.

### BACKGROUND

Piezoelectric resonators, that is, electric resonators based on piezoelectric materials, have found use in various applications such as in sensors and radio frequency (RF) filters. One type of piezoelectric resonator which has seen considerable commercial interest is the so-called thin-film bulk acoustic resonator (FBAR). The thin-film bulk acoustic resonator comprises a piezoelectric material (typically either AlN or ZnO) manufactured using thin film manufacturing methods. The piezoelectric material is arranged between two conductive (metallic) electrodes, and is typically acoustically isolated from the surrounding medium.

In some applications such as sensing and actuation, it is often desirable to excite specifically the thickness shear wave mode of the piezoelectric film of the thin-film bulk acoustic resonator. In the shear wave mode, the motion of the piezoelectric film is perpendicular to the direction of propagation of the wave with no local change of volume. It is well-known that, for example, a thin film of ZnO with c-axis of the crystal structure (crystalline z-axis) tilted at a particular angle relative to the surface of the substrate (roughly 39°) results in optimal coupling to the shear wave mode in the thin film of ZnO while simultaneously minimizing coupling to the longitudinal wave mode. Therefore, it would be beneficial for many applications if the piezoelectric material forming the thin film could be deposited onto the substrate so that the piezoelectric crystals would be oriented in said pre-defined regular manner.

### BRIEF DESCRIPTION

According to an aspect, there is provided the subject matter of the independent claims. Embodiments are defined in the dependent claims.

One or more examples of implementations are set forth in more detail in the accompanying drawings and the description below. Other features will be apparent from the description and drawings, and from the claims.

Some embodiments provide a collimator, use of said collimator in a tilted c-axis axis thin-film deposition process and a deposition system comprising said collimator.

### BRIEF DESCRIPTION OF DRAWINGS

In the following, exemplary embodiments will be described with reference to the attached drawings, in which

FIGS. 1A, 1B and 1C illustrate an exemplary collimator according to an embodiment from above and in two orthogonal cross-sectional side views, respectively;

FIG. 2 illustrates an exemplary collimator according to an embodiment in a perspective view; and

FIG. 3 illustrates a deposition system according to an embodiment.

### DETAILED DESCRIPTION OF SOME EMBODIMENTS

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments.

As is well known in the art, different vibration modes may propagate in a piezoelectric bulk material layer of a bulk acoustic wave (BAW)-based device. These vibration modes may comprise a longitudinal mode and/or one or more of two differently polarized shear modes. The longitudinal mode is characterized by compression and elongation in the direction of the propagation, whereas the shear modes consist of motion perpendicular to the direction of propagation with no local change of volume. Longitudinal and shear waves have different wave velocities. The propagation characteristics of these bulk modes depend on the material properties of the piezoelectric bulk material layer and propagation direction respective to the c-axis orientation. The c-axis may be equally called a crystal axis or a crystallographic axis. The c-axis may be defined, in general, as the (002) direction of a deposited crystal with a hexagonal wurtzite crystal structure. In many applications such as in (fluid-based) sensors applications (e.g., sensors operating in liquid media such as chemical or biochemical sensors), (thickness) shear wave modes are of particular interest due to the fact that shear waves do not impart significant energy into fluids. Specifically, because shear waves exhibit a very low penetration depth into a liquid, a device with pure or predominant shear modes can operate in liquids without significant radiation losses (in contrast to longitudinal waves, which can propagate in liquid and exhibit, thus, significant radiation losses). It is well-known that, for example, a thin film of ZnO with c-axis of the crystal structure tilted at a particular angle relative to the surface of the substrate (roughly 39°) results in optimal coupling to the shear wave mode in the thin film of ZnO while simultaneously minimizing coupling to the longitudinal wave mode. Therefore, it would be beneficial for many applications if the piezoelectric material forming the thin film could be deposited onto the substrate so that the piezoelectric crystals would be oriented in said pre-defined regular manner.

The tilting of the c-axis of the crystal structure may be achieved during deposition, for example, by introducing a collimator (e.g., comprising inclined or slanted blinds or lamels) to the sputtering setup for guiding the sputtered particles. However, current collimator solutions have the disadvantage of causing relatively significant shading due to the relatively large wall thicknesses necessary to ensure thermal and mechanical stability. Since the desired directivity of the collimator already, by necessity, leads to a reduction in the deposition rate, a further exacerbation of this effect by additional shading is undesirable. The large wall thicknesses also limit the minimum meaningful size of the apertures in order to ensure a practically meaningful minimum deposition rate which, in turn, limits the effectivity of the filtering effect of the collimator. Another disadvantage resulting from the shading is that the collimator is coated by the sputtered particles faster and thus the collimator has to be cleaned more often.

The embodiments to be discussed below in detail seek to overcome at least some of the problems outlined above.

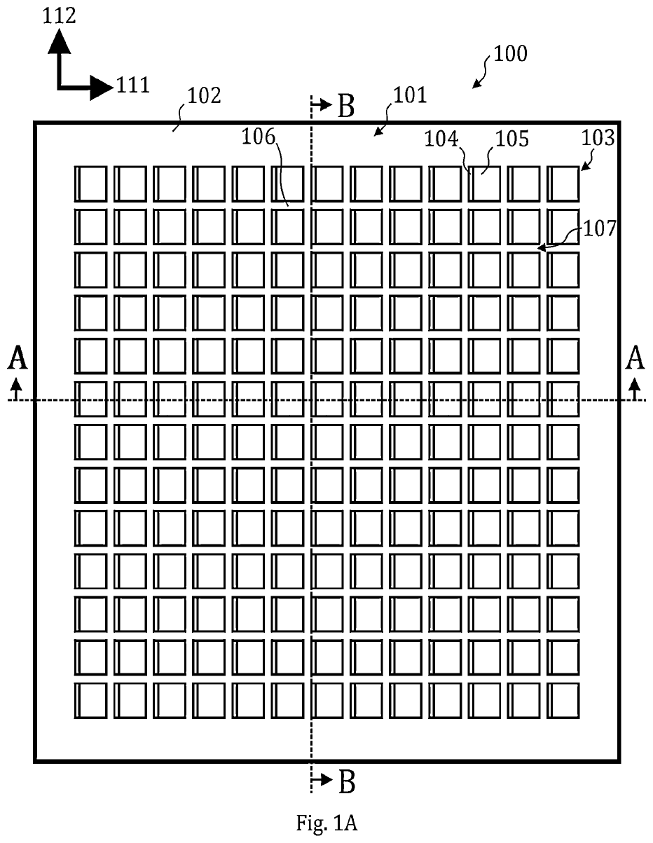

FIGS. 1A, 1B and 1C illustrate an exemplary collimator 100 for a deposition system (for tilted c-axis thin-film deposition) according to an embodiment. The collimator 100 is usable for tilted c-axis deposition. FIGS. 1A, 1B and 1C illustrate the same structure 100 from three different viewpoints: FIG. 1A shows a view from the top while FIGS. 1B and 1C show two orthogonal cross-sectional side views corresponding, respectively, to cut planes A and B as shown in FIG. 1A.

Referring to FIGS. 1A, 1B and 1C, the collimator 100 comprises at least collimator body 101. In some embodiments such as the one illustrated in FIGS. 1A, 1B and 1C, the collimator 100 may consist solely of the collimator body 101.

The collimator body 101 comprises an array of holes 103 for limiting directions of deposition of particles. The array of holes 103 comprises or consists of a plurality of holes 104 penetrating through the collimator body 101, i.e., forming a plurality of (narrow) channels through the collimator body 101. The array of holes 103 may be comprised in a central section or part 107 of the collimator body 101. All or at least some of the plurality of holes 104 are oriented obliquely (i.e., neither parallel nor at right angles) relative to the (plane of) collimator body 101 (or equally relative to a vertical direction being orthogonal to the plane of the collimator body 101) for allowing tilted c-axis deposition, as will be described below in detail. The array 103 extends (i.e., the holes of the array 103 are distributed) along a first horizontal direction 111 (left-right direction in FIG. 1A) and along a second horizontal direction 112 (up-down direction in FIG. 1A) orthogonal to the first horizontal direction 111. A plane defined by the first and second horizontal directions may be called a horizontal plane. The horizontal plane may correspond to a plane of the collimator body 101. In some embodiments such as the one illustrated in FIGS. 1A, 1B and 1C, the array of holes 103 may be a two-dimensional (i.e., planar) rectangular array, that is, an array where the elements are arranged on intersections points of a two-dimensional rectangular grid. In other words, the central section 107 of the collimator body 101 may have a shape of a rectangular mesh (i.e., a mesh where the unit cells are rectangles). FIGS. 1A, 1B and 1C specifically illustrate an array of holes 103 corresponding to a two-dimensional square array. The array of holes 103 may be a periodic array as shown in FIGS. 1A, 1B and 1C, an aperiodic array or a partly aperiodic array (e.g., an array which is periodic along a particular direction but aperiodic along another direction).

While FIGS. 1A, 1B and 1C show a plurality of holes 104 having a square cross section, in other embodiments, other cross-sectional shapes for the holes 104 may be employed such as rectangular, (regular) polygonal, circular or elliptical.

In some alternative embodiments, the array 103 may extend (only) along the first horizontal direction 111, i.e., the holes of the array 103 may be distributed (only) along the first horizontal direction 111. In other words, the array of holes 103 may correspond to a one-dimensional (i.e., linear) array, i.e., to an array where the elements are distributed along a line. Specifically, the array of holes 103 may correspond to a one-dimensional (i.e., linear) periodic array, i.e., to an array where the elements are distributed periodically along a line. In such embodiments, the holes may correspond, for example, to (thin) slits extending along the second horizontal direction 112 (e.g., extending at least over a half of the length of the collimator body 101 along the second horizontal direction 112) or at least along a direction non-parallel to the first horizontal direction 111. The slit-type holes may be oriented at an oblique angle relative to the first horizontal direction 111 (bot not necessarily relative to the second horizontal direction 112).

The plurality of holes 104 in the array of holes 103 may have a width smaller than 10.0 mm, 5.0 mm, smaller than 3.0 mm or smaller than 1.0 mm. Said width for a given hole may be defined along a horizontal plane (defined by the first and second horizontal directions 111, 112) or along a direction orthogonal to the longitudinal direction of the hole (i.e., along a lateral direction of the hole). Said lateral direction may be specifically a non-horizontal direction for obliquely oriented holes (to be discussed below in detail). Alternatively, the array of holes 103 may have a plurality of different widths (e.g., a first section of the array 103 having a different width to a second section of the array), where each of the plurality of different widths (or at least one of them) is smaller than 10.0 mm, 5.0 mm, smaller than 3.0 mm or smaller than 1.0 mm.

At least some or all of the plurality of holes 104 are oriented at one or more oblique angles (θ) relative to a vertical direction 113. The vertical direction 113 is orthogonal to the aforementioned first and second horizontal directions 111, 112 (i.e., it corresponds to an up-down direction in FIGS. 1B & 1C). Thanks to the plurality of holes 104 oriented at oblique angle(s), the collimator 100 may be used for affecting the deposition angle in a deposition system. In other words, the collimator 100 serves to limit the angles at which the deposited particles (e.g., ceramic particles) originating from a source of particles (e.g., a sputtering target such as a magnetron sputtering target) hit the surface of the substrate in the deposition system. This, in turn, affects the c-axis orientation of the formed (piezoelectric) thin film.

In some embodiments, all of the holes of the array 103 may be parallel to each other.

In the illustrated example, all of the plurality of holes 104 of the array 103 are oriented at the same oblique angle θ, where the oblique angle θ corresponds to a rotation or tilting of a vertical hole around the second horizontal direction 112 (up-down direction in FIG. 1A) by θ (but not around the first horizontal direction orthogonal to the second horizontal direction 112), as is shown in FIGS. 1B & 1C. In other embodiments, the plurality of holes 104 may be rotated around multiple different axes.

In some embodiments, the oblique angle θ or, more generally, each of the one or more oblique angles is greater than 25° and/or smaller than 90°, preferably greater than 32° and/or smaller than 75° (or) 85°.

In some embodiments especially suitable for ZnO deposition, the oblique angle θ or, more generally, each of the one or more oblique angles may have, e.g., a value between 25° and 52°, preferably between 30° and 46°. In such embodiments, the angle α may be substantially 39° which corresponds substantially to the angle at which undesired coupling to the longitudinal wave mode is minimized.

In some embodiments especially suitable for AIN deposition the oblique angle θ or, more generally, each of the one or more oblique angles may have, e.g., a value between 25° and 55°, preferably between 33° and 51°. In such embodiments, the angle α may be substantially 47° which corresponds substantially to the angle at which undesired coupling to the longitudinal wave mode is minimized.

The plurality of holes 104 in the array of holes 103 are separated from each other by a plurality of walls 105, 106 (of the central section 107 of the collimator body 101). At least some of the plurality of walls 105 may be inclined or slanted (i.e., arranged at an oblique angle) so as to implement the aforementioned obliquely oriented holes. In other words, at least some of the plurality of walls 105 may be inclined or slanted so as to form a set of inclined blinds or lamels. Optionally, some of the walls 106 may be vertical (i.e., not inclined or slanted).

The plurality of walls may have a wall thickness smaller than or equal to 300 μm, preferably 200 μm, more preferably 100 μm or a plurality of different wall thicknesses each of which (or at least one of which) is smaller than or equal to 300 μm, preferably 200 μm, more preferably 100 μm. By making the wall relatively thin, unnecessary shading effects can be significantly reduced. Additionally, the orientation (or direction) of the sputtering flux (i.e., the particle flux during sputtering) can be significantly improved.

Additionally or alternatively, the plurality of walls 105, 106 may have a wall thickness (or a plurality of wall thicknesses) larger than or equal to 50 μm. By not making the walls extremely thin, the durability of the collimator 100 may be improved.

To give an example of implementing different wall thicknesses in a single structure, the walls 105 arranged parallel to the first horizontal direction 111 may have a first wall thickness while the walls 106 arranged parallel to the second horizontal direction 112 may have a second wall thickness (different from the first wall thickness).

The collimator body 101 or at least the central section 107 of the collimator body 101 may have at least such a thickness or height (being the dimension along the vertical direction 113) which enables directing the sputtering flux substantially to a direction specified by the oblique angle θ. This thickness or height may be, for example, larger than or equal to 3 mm, preferably 5 mm, more preferably 10 mm.

In general, the geometry and dimensions of the collimator body 101 (or at least the central section 107 thereof) may be chosen in such a way that, due to thin walls in combination with narrow channels, undesired shading by the collimator 100 can be minimized and the orientation of the sputtering flux can be improved. This also contributes to the more efficient use of the sputtering target material and enable increasing of the cleaning intervals of the collimator (or the deposition system in general). On the other hand, the improved alignment leads to higher shear coupling of the piezoelectric layer and thus to an improved sensitivity of any sensors manufactured using the collimator 100.

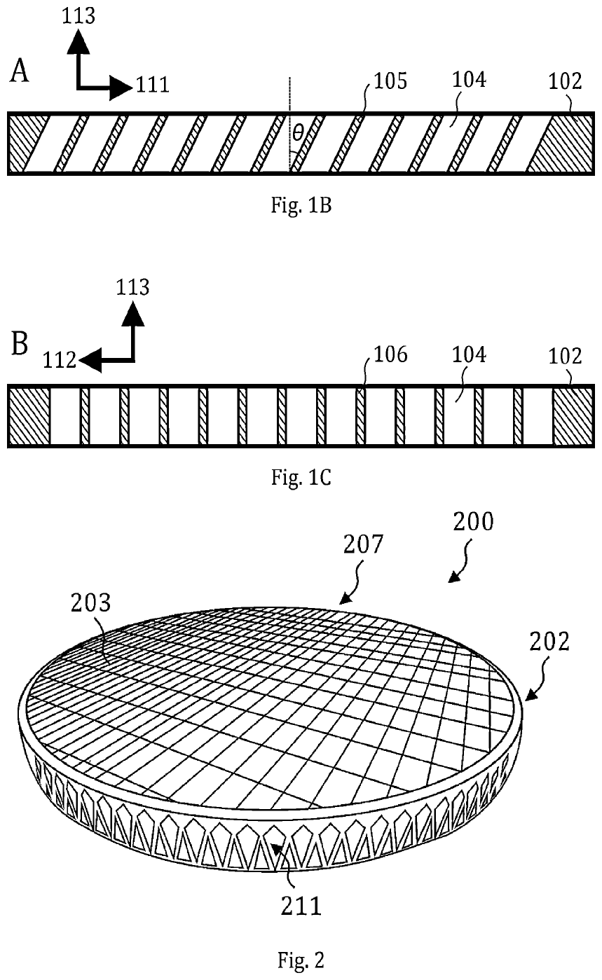

In addition to the central section 107 having the array of holes 103, the collimator body 101 may comprise a frame 102 surrounding, fully or at least in part, the central section 107 (in the horizontal plane). The frame 102 may be arranged at least on or against two opposing sides of the central section 107. The frame 102 may be an integrated frame forming an integrated or intrinsic part of the collimator body 101 (i.e., it is a part of the same single monolithic element). Optionally, the frame 102 may have no holes (or at least no holes suitable for tilted c-axis deposition). The frame 102 may be used for fixing the collimator to a deposition system. The frame 102 may have an (open) grid- or mesh-like or porous structure (i.e., an open lattice structure) for enabling easy depowdering while still ensuring mechanical strength, as will be discussed in detail in connection with FIG. 2. While FIGS. 1A, 1B and 1C show the frame 102 having a square outer and inner shape, in other embodiments, other outer and/or inner shapes for the frame 102 may be employed such as rectangular, (regular) polygonal, circular or elliptical.

In some alternative embodiments not illustrated in FIGS. 1A, 1B and 1C, the frame 102 of the collimator 100 may be implemented as a separate element from the collimator body 101. Such a separate frame may be fixed to the collimator body 101 (e.g., using an adhesive or mechanical means such as screws) following the additive manufacturing.

The collimator body 101 is a (singular) monolithic element. The collimator body 101 may be manufactured using additive manufacturing (i.e., 3D printing). In other words, the collimator body 101 is not formed by manufacturing a plurality of separate elements and subsequently fixing them together but is manufactured as a single piece (e.g., as a single 3D-printed filigree structure in a single processing step). The model of the collimator body 101 for the additive manufacturing may be designed using computer-aided design (CAD) techniques. Use of additive manufacturing enables implementing the thin walls as described above as well as narrow spacing between the adjacent walls (i.e., small hole width) without compromising the durability of the structure. The use of additive manufacturing enables easy implementation of collimator bodies 101 having a variety of different geometries as described above. For example, holes having any cross-sectional shape may be manufactured with ease.

The collimator body 101 may be specifically made of an additive manufacturing material such as a metal-based and/or alloy-based additive manufacturing material. Said metal-based and/or alloy-based additive manufacturing material may be an additive manufacturing material comprising one or more of aluminum, copper, titanium, nickel alloy (e.g., NiCr22Mo9Nb), cobalt-chrome and steel. In general, the material may be selected in such a way that, despite its filigree structure, the collimator 100 is as thermally, mechanically and chemically robust as possible with regard to the planned cleaning process and that the surfaces have good adhesion properties to the material to be deposited, such as ZnO and AlN.

In some embodiments, the material of the collimator body 101 may be selected especially so that the adhesion properties are optimized. For example, the collimator body 101 may be manufactured from a titanium-based material such as TiAl6V4 (equally called Ti-6Al-4V). Additionally or alternatively, the collimator body 101 may be coated with a (thin) adhesive layer such as a TiO₂ layer before use in a deposition system. For example in the case of ZnO deposition, the cleaning may, consequently, be reduced to a short immersion process in a weakly acidic etching solution followed by rinsing in deionized (DI) water and drying.

In some embodiments, the collimator body 101 may comprise integrated mechanical fastening means (or equally integrated attaching means) built additively with the rest of the collimator body 101 in one production step, so that assembly can be precise and straightforward and without risk of damage. The integrated mechanical fastening means may be configured to enable fastening or attaching the collimator 100 to a deposition system or specifically to a particular fastening element of the deposition system. The integrated mechanical fastening means may extend or protrude (at least) from the frame 102 of the collimator body 101. Additionally or alternatively, the integrated mechanical fastening means may be provided on the frame 102 of the collimator body 101 (e.g., at least cavity or notch for enabling fastening may be arranged on the frame 102 of the collimator body 101). The mechanical fastening means may comprise, for example, at least one mechanical clipping or clamping element or at least one element onto which a mechanical clipping or clamping element (of the deposition system) may be attached.

Additionally or alternatively, the collimator body 101 may comprise a substrate support structure (or substrate supporting means) for enabling placing and supporting the substrate at a pre-defined distance from the collimator 100. Said substrate supporting means may corresponds to a protrusion, as discussed in more detail in connection with FIG. 2. Such substrate supporting means may be employed especially with deposition systems using a sputter-up configuration. The substrate supporting means may extend or protrude at least from the frame 102 of the collimator body 101.

The process of additive manufacturing can also be advantageously designed in such a way that the surfaces of the filigree structures, similar to the adhesive layers, permanently have a strong micro-roughness and thus good adhesion properties. Said strong micro-roughness may correspond, for example, to a roughness of at least 100 μm RMS (root mean square).

FIG. 2 illustrates a collimator 200 according to an embodiment. Any of the definitions provided in connection with FIGS. 1A, 1B and 1C may apply, mutatis mutandis, for the collimator 200 unless otherwise stated.

Similar to as described in connection with FIGS. 1A, 1B and 1C, the collimator 200 comprises at least a collimator body 201. The collimator body 201 comprises a central section 207 having an array of obliquely oriented holes 203 and a frame 202 surrounding, fully or at least in part, the central section 207. The central section 207 is illustrated in FIG. 2 only schematically (i.e., not showing obliquely oriented holes and the walls separating them in detail) for simplicity of presentation. The central section 207 having the array of obliquely oriented holes 203 and the frame 202 form, together, to a singular monolithic element (manufactured using additive manufacturing). In other words, the frame 202 is an integrated (or intrinsic) frame of the collimator body 201.

In FIG. 2, the frame 202 is a (fully) circular frame, that is, both inner and outer shapes (or inner and outer contours) of the frame 202 are circular.

The frame 202 has an (open) grid- or mesh-like or porous structure for enabling easy depowdering while still ensuring mechanical strength. Specifically, the frame comprises a plurality of cavities or holes 211 penetrating through the frame (e.g., in a radial direction of the circular frame 202 or in any other direction which is non-orthogonal with the radial direction). As shown in FIG. 2, at least some of the plurality of cavities or holes 211 may be arranged on the (outer) side(s) of the frame 202. The plurality of cavities or holes 211 may be spread around the circumference of the frame 200 (e.g., in a uniform manner).

In other embodiments, at least some of the plurality of cavities or holes 211 may penetrate through the frame 202 (substantially) along a vertical direction (being a direction orthogonal to the plane of the collimator body 201).

While each of the holes or cavities 211 shown in FIG. 2 has a diamond-shape and or a triangular shape, other shape or shapes (e.g., rectangular) may be used in other embodiments. In some embodiments, the frame may comprise multiple cavities arranged on top of each other (e.g., multiple layers of the diamond/triangle cavity pattern of FIG. 2 arranged on top of each other).

While FIG. 2 shows a circular frame 202, similar plurality of cavities 211 may be arranged equally around a frame of any other shape such as rectangular, square, (regular) polygonal or elliptical shapes.

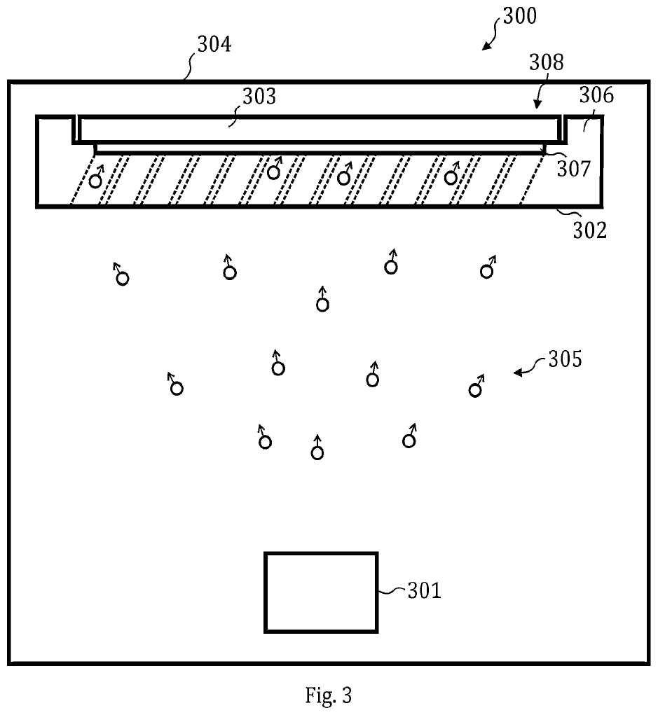

FIG. 3 illustrates an exemplary deposition system 300 according to an embodiment for tilted c-axis thin-film deposition. FIG. 3 illustrates the depositions system 300 from the side in a view similar to FIG. 1B or 1C (though FIG. 3 does not show a cross-sectional view). The obliquely oriented holes penetrating the collimator 302 are shown with dashed lines. The deposition system 300 may comprise or be arranged in a vacuum chamber 304 which may comprise, during deposition, inert gas such as argon. The deposition system 300 may be specifically a system for physical vapor deposition or more specifically sputtering (e.g., magnetron sputtering). The deposition system 300 may correspond specifically to a sputter-up configuration, as depicted in FIG. 3.

The deposition system 300 comprises at least a source of (ceramic) particles 301 for producing (ceramic) particle 305 and a collimator 302 fixed in front of the source 301 for limiting directions of deposition of the particles. In other words, the plurality of inclined holes provided in the collimator body of the collimator cause the sputtered particles 305 to align along a particular direction defined by the oblique angle at which the holes are inclined.

The source of particles 301 may comprise, for example, a (magnetron) sputtering target (e.g., an Al target). The source of particles 301 may be mounted or supported by a source support (not shown in FIG. 3).

The (reactive) sputtering process may proceed, e.g., as follows. A gaseous plasma is generated from said inert gas (e.g., Ar) and confined to a space containing the sputtering target (acting as a cathode). A reactive gas (e.g., N₂ or O₂) is introduced into the plasma. The surface of the sputtering target is eroded by high-energy ions within the plasma. The liberated particles travel through the vacuum chamber 301 which causes them to react with the reactive gas. Subsequently, the formed particles (e.g., AlN particles) are deposited, via the collimator 302, onto a substrate 303 (acting as an anode) to form a thin film.

The (reactive) sputtering process may employ specifically magnetron sputtering. Magnetron sputtering uses specifically magnets to trap electrons over the negatively charged sputtering target so they are not free to bombard the substrate 303, preventing the object to be coated from overheating or being damaged, and allowing for a faster thin film deposition rate.

The collimator 303 may be a collimator according to embodiments as discussed in connection with FIG. 1A, 1B, 1C and/or 2.

FIG. 3 also shows a substrate 303 (or a wafer) which is mounted, in this example, directly on the collimator 302 (i.e., on the additively manufactured collimator body). Due to the inclined holes of the collimator 302, the particles 305 hit the substrate at a particular angle enabling growing a (thin) film with a tilted c-axis. Any substrate can be used as the substrate 303. The substrate 303 may be preferably a semiconductor substrate with a semiconductor material (e.g., silicon and/or gallium arsenide). The substrate 303 may be single crystalline or polycrystalline. The formed film may be a ceramic film produced with a ceramic selected from the group aluminum nitride (AlN) and/or zinc oxide (ZnO) and/or scandium aluminum nitride (Sc_{X}Al_{1-X}N). The film deposited on the substrate 303 may form a piezoelectric layer of a thin-film bulk acoustic resonator (FBAR).

The collimator body (or specifically the frame thereof) comprises a substrate support structure 306 extending from or provided on the frame of the collimator body. In FIG. 3, the substrate support structure corresponds specifically to a protrusion 306 protruding from the frame of the collimator body. The substrate support structure 306 enables placing the substrate 303 at a pre-defined distance from the collimator 302 (thus forming a gap 307 between the collimator 302 and the substrate 303). Moreover, the substrate support structure 306 provides a recess 308 into which the substrate 303 may be inserted. Said substrate support structure 306 (e.g., the protrusion) may form an integrated or intrinsic part of the collimator body manufactured with the rest of the collimator body using additive manufacturing (in a single process step).

The deposition system 300 of FIG. 3 having the protrusion 306 or other such integrated substrate support structure provided in (the frame of) the collimator body provides the benefit that the substrate 303 (i.e., the wafer) may be easily placed in close vicinity of the collimator 302 which, in turn, serves to facilitate the sputtering (e.g., in terms of placing less stringent requirements for pressure needed in the deposition system). Another benefit is that the collimator 302 may be moved to the deposition system (i.e., to the vacuum chamber thereof) with the substrate 303. Thus, the collimator 302 may be easily cleaned after each sputtering and therefore the maintenance of the deposition system 300 is facilitated.

In some alternative embodiments, a separate substrate support element (i.e., a substrate holder) which does not form a part of the collimator 302 or at least not an integrated or intrinsic part of the collimator body may be provided. Said separate substrate support element may enable placing the substrate at a predefined distance from the collimator 302. In such embodiments, the protrusion 306 in the frame of the collimator body may be omitted (i.e., the collimator 302 may have a rectangular side profile).

Even though the invention has been described above with reference to examples according to the accompanying drawings, it is clear that the invention is not restricted thereto but it can be modified in several ways within the scope of the appended claims. Therefore, all words and expressions should be interpreted broadly and they are intended to illustrate, not to restrict, the embodiment. It will be obvious to a person skilled in the art that, as technology advances, the inventive concept can be implemented in various ways.

1. A collimator for tilted c-axis thin-film deposition, comprising:
a collimator body comprising an array of holes for limiting directions of deposition of particles, wherein the collimator body is a singular monolithic element,
wherein the array of holes comprises a plurality of holes oriented at one or more oblique angles relative to a vertical direction, the vertical direction being orthogonal to the first and second horizontal directions,
wherein the collimator body comprises a central section comprising said array of holes and an integrated frame surrounding, fully or at least in part, the central section,
wherein the collimator body comprises an integrated substrate support structure extending from or provided on the integrated frame for holding or supporting a substrate.

2. The collimator of claim 1, wherein the array is a one-dimensional array extending along a first horizontal direction or a two-dimensional array extending along the first horizontal direction and a second horizontal direction orthogonal to the first horizontal direction.

3. (canceled)

4. The collimator according to claim 1, wherein each of the one or more oblique angles is greater than 25° and smaller than 90°, preferably greater than 32° and smaller than 75°.

5. The collimator according to claim 1, wherein a width of the plurality of holes or each of a plurality of different widths of the plurality of holes is smaller than 10.0 mm, or smaller than 5.0 mm, or smaller than 3.0 mm, or smaller than 1 mm.

6. The collimator according to claim 1, wherein the array of holes is a one-dimensional periodic array or a two-dimensional periodic array.

7. The collimator according to claim 1, wherein the collimator body comprises a plurality of walls separating holes of the array, the plurality of walls having a wall thickness smaller than or equal to 300 μm, preferably 200 μm, more preferably 100 μm, and larger than or equal to 50 μm or a plurality of different wall thicknesses smaller than or equal to 300 μm, preferably 200 μm, more preferably 100 μm, and larger than or equal to 50 μm.

8. The collimator according to claim 1, wherein the collimator body is metal-based or alloy-based material, preferably titanium-based material.

9. (canceled)

10. The collimator according to claim 1, wherein the integrated frame has a mesh-like or porous structure.

11. The collimator according to claim 1, wherein the collimator body comprises
integrated mechanical fastening means extending from or provided on the integrated frame for fastening the collimator to a deposition system.

12. (canceled)

13. The collimator according to claim 1, wherein a surface of the collimator body is coated with an adhesive layer, being preferably a layer of TiO₂.

14. Use of a collimator according to claim 1 in a tilted c-axis axis thin-film deposition process.

15. A deposition system comprising:
a source of particles for producing particles for deposition;
a collimator according to claim 1 arranged in front of the source of particles for limiting directions of deposition of the particles.

16. A method for manufacturing a collimator according to claim 1. the method comprising manufacturing the collimator body of the collimator using additive manufacturing.
